(19) United States
(12) Patent Application Publication
(10) Pub. No.: US 2025/0376759 A1
(43) Pub. Date: Dec. 11, 2025

(54) MASK STAGE AND DEPOSITION APPARATUS INCLUDING THE SAME

(71) Applicant: Samsung Display Co., LTD., Yongin-si (KR)

(72) Inventors: Jin Yong LEE, Yongin-si (KR); Il Soo LEE, Yongin-si (KR); Kyong Tae YU, Yongin-si (KR)

(73) Assignee: Samsung Display Co., LTD., Yongin-si (KR)

(21) Appl. No.: 19/012,121

(22) Filed: Jan. 7, 2025

(30) Foreign Application Priority Data
Jun. 7, 2024 (KR) 10-2024-0074137

(51) Int. Cl. C23C 16/04; H10H 29/01; H10K 59/12

(52) U.S. Cl. CPC C23C 16/042; H10H 29/012; H10K 59/1201

(57) ABSTRACT

A mask stage includes an electrostatic chuck having a plate shape in a plan view through which a through hole is formed and supporting an edge portion of a deposition mask, and a lattice support disposed in the through hole and supporting a remaining portion of the deposition mask other than the edge portion. The electrostatic chuck includes a chucking region having a ring shape in a plan view disposed around the through hole to hold the edge portion of the deposition mask using an electrostatic force.

### CROSS-REFERENCE TO RELATED APPLICATION(S)

This application claims priority to and benefits of Korean Patent Application No. 10-2024-0074137 under 35 U.S.C. § 119, filed on Jun. 7, 2024, in the Korean Intellectual Property Office (KIPO), the entire contents of which are incorporated herein by reference.

### BACKGROUND

### 1. Technical Field

The disclosure relates to a mask stage, a deposition apparatus including the mask stage, and an electronic device manufactured by using the deposition apparatus.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

In the case of wearable devices such as the HMD device or the AR glasses, a display specification of approximately 3000 PPI (pixels per inch) or higher is required to allow users to use them for a long time without symptoms of dizziness. To this end, organic light-emitting diode on silicon (OLEDoS) technology used in high-resolution small-sized organic light-emitting display devices is emerging. The OLEDOS is a technology in which organic light-emitting diodes (OLEDs) are disposed on a semiconductor wafer substrate on which complementary metal oxide semiconductor (CMOS) elements are disposed.

In order to manufacture a high-resolution display panel of about 3000 PPI or higher, a high-resolution deposition mask is required. For example, a deposition mask may be manufactured by forming a membrane having a plurality of pixel openings on a substrate such as a silicon wafer, and partially etching the substrate to form cell openings that expose the pixel openings. In a deposition process for forming organic light-emitting layers on a backplane substrate, the backplane substrate may be disposed on the deposition mask, and an organic material may be deposited on the backplane substrate through the pixel openings of the deposition mask. However, in the case of manufacturing the deposition mask using a silicon wafer, a phenomenon that the membrane of the deposition mask sags downward may occur during the deposition process, so that the gap between the backplane substrate and the membrane may increase, and misalignment may occur between organic light-emitting layers and anode electrodes on the backplane substrate.

### SUMMARY

Aspects and features of embodiments of the disclosure provide a mask stage capable of preventing sagging of a deposition mask, a deposition apparatus including the mask stage, and an electronic device manufactured by using the deposition apparatus.

However, embodiments of the disclosure are not limited to those set forth herein. The above and other embodiments of the disclosure will become more apparent to one of ordinary skill in the art to which the disclosure pertains by referencing the detailed description of the disclosure given below.

According to one or more embodiments of the disclosure, a mask stage may include an electrostatic chuck having a plate shape in a plan view through which a through hole is formed and supporting an edge portion of a deposition mask, and a lattice support disposed in the through hole and supporting a remaining portion of the deposition mask other than the edge portion. The electrostatic chuck may include a chucking region having a ring shape in a plan view disposed around the through hole to hold the edge portion of the deposition mask using an electrostatic force.

The deposition mask may include a plurality of cell regions and a grid region disposed between the plurality of cell regions. The lattice support may include a lattice plate supporting the grid region of the deposition mask, and a support ring extending downward from an edge portion of the lattice plate.

The lattice plate may have a thickness in a range of about 5 mm to about 6 mm.

The lattice support may further include a flange surrounding a lower portion of the support ring and a mount bracket protruding radially outward from the flange, and a stepped portion into which the flange and the mount bracket are inserted may be provided at a bottom surface portion of the electrostatic chuck.

The lattice support may be made of precipitation hardening stainless steel.

The electrostatic chuck may further include a first electrostatic electrode disposed in the chucking region, and a second electrostatic electrode disposed in the chucking region. A first electrostatic voltage may be applied to the first electrostatic electrode, and a second electrostatic voltage having a polarity different from the first electrostatic voltage may be applied to the second electrostatic electrode.

The chucking region may have a circular ring shape in a plan view, and the first electrostatic electrode may have a circular ring shape in a plan view extending along the chucking region. The second electrostatic electrode may have a circular ring shape in a plan view surrounding the first electrostatic electrode, and may be spaced apart from the first electrostatic electrode by a predetermined gap. The first electrostatic electrode and the second electrostatic electrode may be disposed at a same height.

The first electrostatic electrode may have a meandering structure extending along the chucking region, and the second electrostatic electrode may extend along the first electrostatic electrode.

The chucking region may have a circular ring shape in a plan view. The first electrostatic electrode may include a first ring electrode formed in a circular ring shape in a plan view extending along the chucking region, and a plurality of first branch electrodes extending radially outward from the first ring electrode. The second electrostatic electrode may include a second ring electrode formed in a circular ring shape in a plan view surrounding the first electrostatic electrode, and a plurality of second branch electrodes extending radially inward from the second ring electrode. The plurality of first branch electrodes and the plurality of second branch electrodes may be alternately arranged in a circumferential direction.

According to one or more embodiments of the disclosure, a deposition apparatus may include a deposition source, a mask stage disposed above the deposition source and on which a deposition mask is placed, and an upper chuck disposed above the mask stage to hold a back surface of a substrate such that a front surface of the substrate faces the deposition mask. The mask stage may include an electrostatic chuck having a plate shape through which a through hole is formed and supporting an edge portion of the deposition mask, and a lattice support disposed in the through hole and supporting a remaining portion of the deposition mask other than the edge portion. The electrostatic chuck may include a chucking region having a ring shape in a plan view disposed around the through hole to hold the edge portion of the deposition mask using an electrostatic force.

The deposition mask may include a plurality of cell regions and a grid region disposed between the plurality of cell regions. The lattice support may include a lattice plate supporting the grid region of the deposition mask, and a support ring extending downward from an edge portion of the lattice plate.

The lattice plate may have a thickness in a range of about 5 mm to about 6 mm.

The lattice support may further include a flange surrounding a lower portion of the support ring and a mount bracket protruding radially outward from the flange. A stepped portion into which the flange and the mount bracket are inserted may be provided at a bottom surface portion of the electrostatic chuck.

The lattice support may have an alignment hole penetrating the flange, and the electrostatic chuck may have an alignment slot corresponding to the alignment hole and formed at an inner surface portion of the through hole. An alignment key of the deposition mask may be aligned with the alignment hole and the alignment slot.

The mask stage may have an alignment hole aligned with an alignment key of the deposition mask.

The lattice support may be made of precipitation hardening stainless steel.

The electrostatic chuck may further include a first electrostatic electrode disposed in the chucking region, and a second electrostatic electrode disposed in the chucking region. A first electrostatic voltage may be applied to the first electrostatic electrode, and a second electrostatic voltage having a polarity different from the first electrostatic voltage may be applied to the second electrostatic electrode.

The chucking region may have a circular ring shape in a plan view, and the first electrostatic electrode may have a circular ring shape in a plan view extending along the chucking region. The second electrostatic electrode may have a circular ring shape in a plan view surrounding the first electrostatic electrode, and may be spaced apart from the first electrostatic electrode by a predetermined gap. The first electrostatic electrode and the second electrostatic electrode may be disposed at a same height.

The first electrostatic electrode may have a meandering structure extending along the chucking region, and the second electrostatic electrode may extend along the first electrostatic electrode.

The chucking region may have a circular ring shape in a plan view. The first electrostatic electrode may include a first ring electrode formed in a circular ring shape in a plan view extending along the chucking region, and a plurality of first branch electrodes extending radially outward from the first ring electrode. The second electrostatic electrode may include a second ring electrode formed in a circular ring shape in a plan view surrounding the first electrostatic electrode, and a plurality of second branch electrodes extending radially inward from the second ring electrode. The plurality of first branch electrodes and the plurality of second branch electrodes may be alternately arranged in a circumferential direction.

According to one or more embodiments of the disclosure, an electronic device may include a display panel including a substrate and light-emitting layers formed on the substrate by using a deposition apparatus. The deposition apparatus may include a deposition source, a mask stage disposed above the deposition source and on which a deposition mask is placed, and an upper chuck disposed above the mask stage to hold a back surface of the substrate such that a front surface of the substrate faces the deposition mask. The mask stage may include an electrostatic chuck having a plate shape through which a through hole is formed and supporting an edge portion of the deposition mask, and a lattice support disposed in the through hole and supporting a remaining portion of the deposition mask other than the edge portion. The electrostatic chuck may include a chucking region having a ring shape in a plan view disposed around the through hole to hold the edge portion of the deposition mask using an electrostatic force.

In accordance with embodiments of the disclosure, the sagging of the deposition mask may be prevented by a lattice support of the mask stage, and accordingly, the deposition mask may be sufficiently brought into close contact with the substrate during the deposition process.

Other features and embodiments may be apparent from the following detailed description and the drawings.

### BRIEF DESCRIPTION OF THE DRAWINGS

The above and other aspects and features of the disclosure will become more apparent by describing in detail embodiments thereof with reference to the attached drawings, in which:

FIG. 1 is an exploded perspective view illustrating a display device;

FIG. 2 is a schematic block diagram for explaining the display device shown in FIG. 1;

FIG. 3 is a schematic diagram of an equivalent circuit of a first sub-pixel shown in FIG. 2 according to an embodiment;

FIG. 4 is a schematic plan view illustrating an embodiment of the display panel shown in FIG. 1;

FIG. 5 is a schematic plan view illustrating an embodiment of the display area shown in FIG. 4;

FIG. 6 is a schematic plan view illustrating another embodiment of the display area shown in FIG. 4;

FIG. 7 is a schematic cross-sectional view illustrating an embodiment of the display panel taken along line I-I′ of FIG. 5;

FIG. 8 is a schematic perspective view illustrating an embodiment of a head mounted display;

FIG. 9 is a schematic exploded perspective view illustrating the head mounted display shown in FIG. 8;

FIG. 10 is a schematic perspective view illustrating another embodiment of a head mounted display;

FIG. 11 is a schematic cross-sectional view illustrating a mask stage and a deposition apparatus including the mask stage according to an embodiment of the disclosure;

FIG. 12 is a schematic plan view illustrating a substrate shown in FIG. 11;

FIG. 13 is a schematic plan view illustrating a deposition mask shown in FIG. 11;

FIG. 14 is a schematic enlarged plan view illustrating mask cell regions shown in FIG. 13;

FIG. 15 is a schematic cross-sectional view taken along line II-II′ shown in FIG. 14;

FIG. 16 is a schematic plan view illustrating the mask stage shown in FIG. 11;

FIG. 17 is a schematic cross-sectional view taken along line III-III′ shown in FIG. 16;

FIG. 18 is a schematic cross-sectional view illustrating an electrostatic chuck and a lattice support shown in FIG. 17;

FIG. 19 is a schematic plan view illustrating the electrostatic chuck shown in FIG. 16;

FIG. 20 is a schematic bottom view illustrating the electrostatic chuck shown in FIG. 16;

FIG. 21 is a schematic plan view illustrating the lattice support shown in FIG. 16;

FIG. 22 is a schematic enlarged plan view illustrating first and second electrostatic electrodes shown in FIG. 16; and

FIG. 23 is a schematic enlarged plan view illustrating another embodiment of the first and second electrostatic electrodes shown in FIG. 22.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on another layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, ±20%, ±10%, ±5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

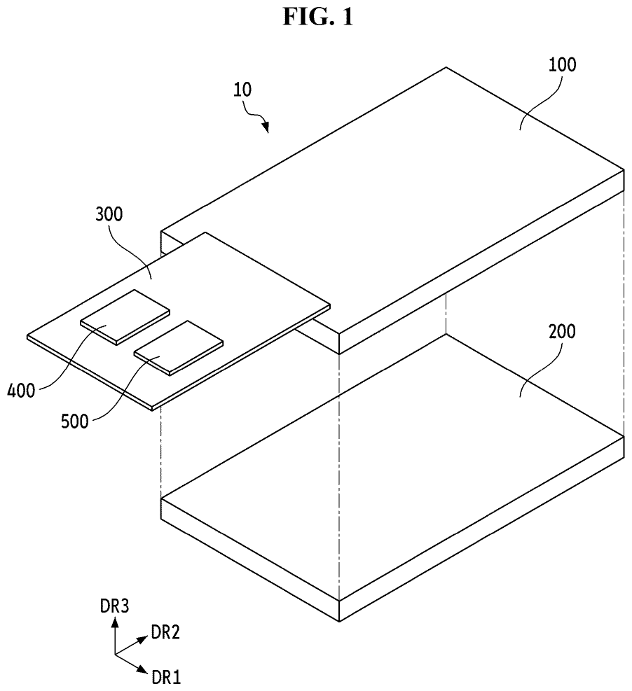

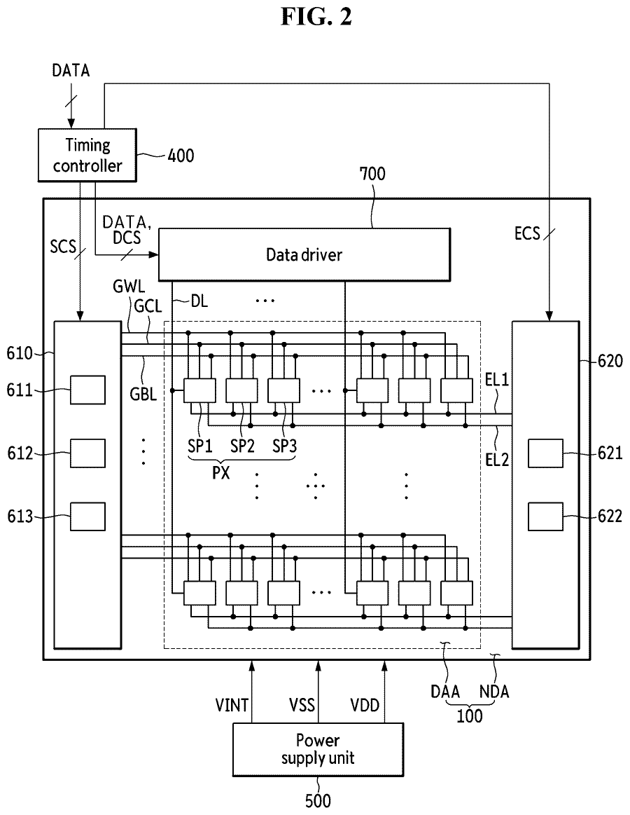

FIG. 1 is an exploded perspective view illustrating a display device. FIG. 2 is a schematic block diagram for explaining the display device shown in FIG. 1.

Referring to FIGS. 1 and 2, a display device 10 may be a device displaying a moving image or a still image. The display device 10 may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. The display device 10 may be also applied to a smart watch, a watch phone, a head mounted display (HMD) for implementing virtual reality and augmented reality, and the like.

The display device 10 may include a display panel 100, a heat dissipation layer 200, a circuit board 300, a timing control circuit 400, and a power supply unit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1 in a plan view. In the display panel 100, a corner where a short side in the first direction DR1 and a long side in the second direction DR2 meet may be right-angled or rounded with a curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the disclosure is not limited thereto.

The display panel 100 may include multiple pixels PX, multiple scan lines SL, multiple emission control lines EL, multiple data lines DL, a scan driver 610, an emission driver 620, and a data driver 700. As shown in FIG. 2, the display panel 100 may be divided into a display area DAA displaying an image and a non-display area NDA not displaying an image.

The pixels PX may be disposed in the display area DAA. The pixels PX may be arranged in a matrix form along the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL may include multiple write scan lines GWL, multiple control scan lines GCL, and multiple bias scan lines GBL. The emission control lines EL may include multiple first emission control lines EL1 and multiple second emission control lines EL2.

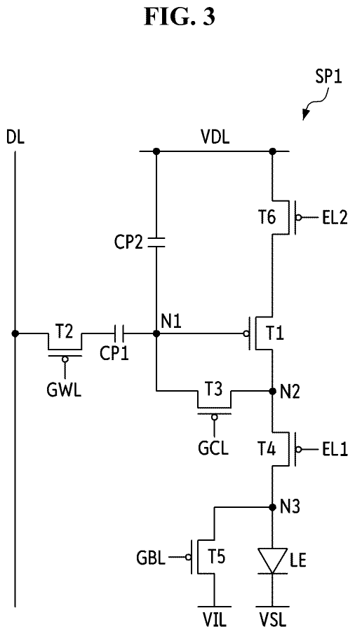

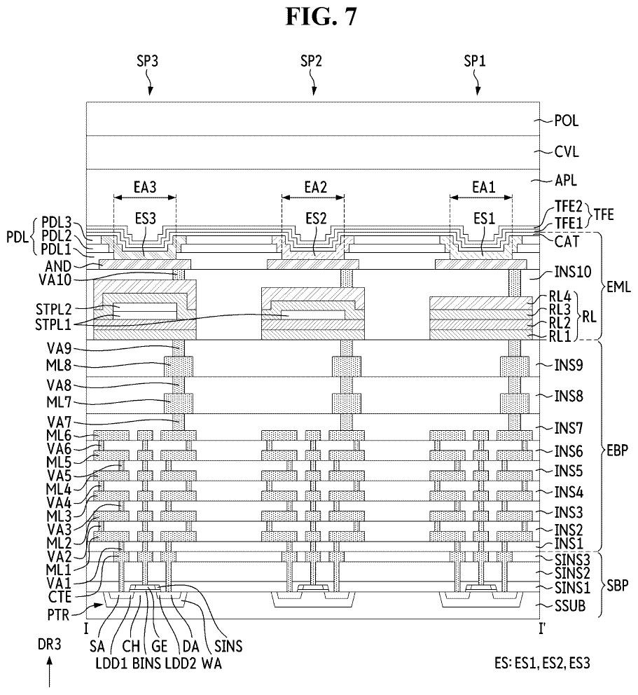

The pixels PX may include multiple sub-pixels SP1, SP2, and SP3. The sub-pixels SP1, SP2, and SP3 may include multiple pixel transistors (see FIG. 3). The pixel transistors may be formed by a semiconductor process, and may be disposed on a semiconductor substrate SSUB (see FIG. 7). For example, the pixel transistors of the data driver 700 may be formed through a complementary metal oxide semiconductor (CMOS) process, but the disclosure is not limited thereto.

Each of the sub-pixels SP1, SP2, and SP3 may be connected to one write scan line GWL among the write scan lines GWL, one control scan line GCL among the control scan lines GCL, one bias scan line GBL among the bias scan lines GBL, one first emission control line EL1 among the first emission control lines EL1, one second emission control line EL2 among the second emission control lines EL2, and one data line DL among the data lines DL. Each of the sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include multiple scan transistors, and the emission driver 620 may include multiple light-emitting transistors. The scan transistors and the light-emitting transistors may be formed on the semiconductor substrate SSUB (see FIG. 7) through a semiconductor process. For example, the scan transistors and the light-emitting transistors may be formed through a CMOS process, but the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output the write scan signals sequentially to the write scan lines GWL. The control scan signal output unit 612 may generate control scan signals in response to the scan timing control signal SCS and sequentially output the control scan signals to the control scan lines GCL. The bias scan signal output unit 613 may generate bias scan signals according to the scan timing control signal SCS and output the bias scan signals sequentially to bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include multiple data transistors, and the data transistors may be formed through a semiconductor process, and formed on the semiconductor substrate SSUB (see FIG. 7). For example, the data transistors may be formed through a CMOS process, but the disclosure is not limited thereto.

The data driver 700 may receive digital video data DATA and a data timing control signal DCS from the timing control circuit 400. The data driver 700 may convert the digital video data DATA into analog data voltages according to the data timing control signal DCS and outputs the analog data voltages to the data lines DL. The sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on a surface of the display panel 100, for example, on the rear surface of the display panel 100. The heat dissipation layer 200 may serve to dissipate heat generated from the display panel 100. The heat dissipation layer 200 may include a metal layer having high thermal conductivity, such as graphite, silver (Ag), copper (Cu), or aluminum (Al).

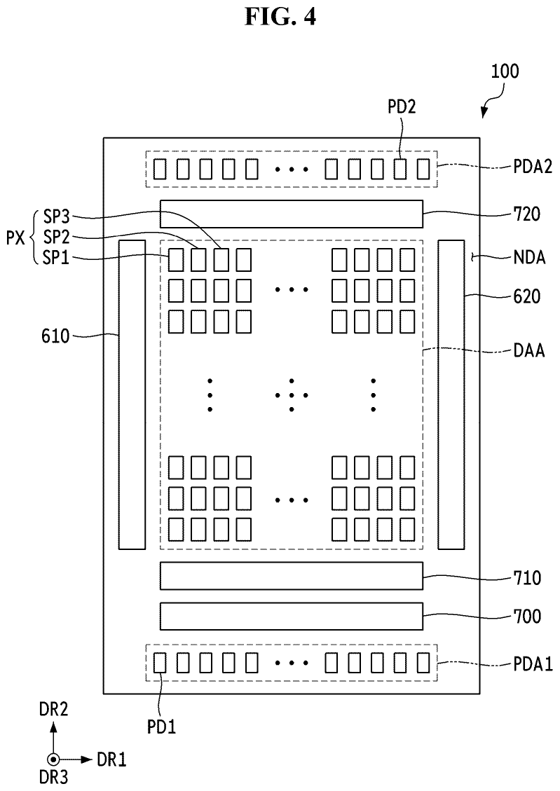

The circuit board 300 may be electrically connected to multiple first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. An end of the circuit board 300 may be disposed on the rear surface of the display panel 100 and/or the rear surface of the heat dissipation layer 200. Another end of the circuit board 300 may be connected to the first pads PD1 (see FIG. 4) of the first pad portion PDA1 (see FIG. 4) of the display panel 100 by using a conductive adhesive member. The end of the circuit board 300 may be an opposite end of the another end of the circuit board 300.

The timing control circuit 400 may receive digital video data and timing signals input from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply unit 500 may generate multiple panel driving voltages according to a power voltage from the outside. For example, the power supply unit 500 may generate a first driving voltage VSS, a second driving voltage VDD, and a third driving voltage VINT and supply them to the display panel 100. The first driving voltage VSS, the second driving voltage VDD, and the third driving voltage VINT will be described below in conjunction with FIG. 3.

Each of the timing control circuit 400 and the power supply unit 500 may be formed as an integrated circuit (IC) and attached to a surface of the circuit board 300. The scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply unit 500 may be supplied to the display panel 100 through the circuit board 300.

In another embodiment, each of the timing control circuit 400 and the power supply unit 500 may be disposed in the non-display area NDA of the display panel 100, similarly to the scan driver 610, the emission driver 620, and the data driver 700. The timing control circuit 400 may include multiple timing transistors, and each power supply unit 500 may include multiple power transistors. The timing transistors and the power transistors may be formed through a semiconductor process, and formed on the semiconductor substrate SSUB (see FIG. 7). For example, the timing transistors and the power transistors may be formed through a CMOS process, but the disclosure is not limited thereto. Each of the timing control circuit 400 and the power supply unit 500 may be disposed between the data driver 700 and the first pad portion PDA1 (see FIG. 4).

FIG. 3 is a schematic diagram of an equivalent circuit of a first sub-pixel shown in FIG. 2 according to an embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which a first driving voltage VSS corresponding to a low potential voltage is applied, a second driving voltage line VDL to which a second driving voltage VDD corresponding to a high potential voltage is applied, and a third driving voltage line VIL to which a third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. The first driving voltage VSS may be lower than the third driving voltage VINT. The second driving voltage VDD may be higher than the third driving voltage VINT.

The first sub-pixel SP1 may include multiple transistors T1 to T6, a light-emitting element LE, a first capacitor CP1, and a second capacitor CP2.

The light-emitting element LE may emit light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In another embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter also referred to as “driving current”) flowing between the source electrode and the drain electrode thereof according to a voltage applied to the gate electrode of the first transistor T1. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL to connect the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the control scan signal of the control scan line GCL to connect the first node N1 to the second node N2. For this reason, in case that the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3.

Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction between the gate electrode of the first transistor T1, the drain electrode of the third transistor T3, the another electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the disclosure is not limited thereto. In another embodiment, each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the first sub-pixel SP1 is not limited to that shown in FIG. 3. For example, the number of transistors and the number of capacitors of the first sub-pixel SP1 are not limited to those shown in FIG. 3.

Further, the second sub-pixel SP2 and the third sub-pixel SP3 may be substantially the same as the first sub-pixel SP1 described in conjunction with FIG. 3. Therefore, the description of the second sub-pixel SP2 and the third sub-pixel SP3 will be omitted in the disclosure.

FIG. 4 is a schematic plan view illustrating an embodiment of the display panel shown in FIG. 1.

Referring to FIG. 4, the display area DAA of the display panel 100 may include the pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on a side of the display area DAA in the first direction DR1, and the emission driver 620 may be disposed on another side of the display area DAA in the first direction DR1. For example, as shown in FIG. 4, the scan driver 610 may be disposed on the left side of the display area DAA, and the emission driver 620 may be disposed on the right side of the display area DAA. However, the disclosure is not limited thereto, and the scan driver 610 and the emission driver 620 may be disposed on both the first side and the second side of the display area DAA.

The first pad portion PDA1 may include the first pads PD1 connected to pads or bumps of the circuit board 300 through a conductive adhesive member. The first pad portion PDA1 may be disposed on the third side of the display area DAA. For example, the first pad portion PDA1 may be disposed on a side of the display area DAA in the second direction DR2. The first pad portion PDA1 may be disposed outside the data driver 700 in the second direction DR2. For example, as shown in FIG. 4, the first pad portion PDA1 may be disposed closer to the edge of the display panel 100 than the data driver 700.

The second pad portion PDA2 may include multiple second pads PD2 corresponding to inspection pads that test whether the display panel 100 operates normally. The second pads PD2 may be connected to a jig or probe pins during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. For example, the second pad portion PDA2 may be disposed on another side of the display area DAA in the second direction DR2. The second pad portion PDA2 may be disposed outside the second distribution circuit 720 in the second direction DR2. For example, as shown in FIG. 4, the second pad portion PDA2 may be disposed closer to the edge of the display panel 100 than the second distribution circuit 720.

The first distribution circuit 710 may distribute data voltages applied through the first pad portion PDA1 to the data lines DL. For example, the first distribution circuit 710 may distribute the data voltages applied through one first pad PD1 of the first pad portion PDA1 to the P (P is a positive integer of 2 or more) data lines DL, and as a result, the number of the first pads PD1 may be reduced. The first distribution circuit 710 may be disposed on the third side of the display area DAA of the display panel 100. For example, the first distribution circuit 710 may be disposed on a side of the display area DAA in the second direction DR2. For example, as shown in FIG. 4, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on another side of the display area DAA in the second direction DR2. For example, as shown in FIG. 4, the second distribution circuit 720 may be disposed on the upper side of the display area DAA.

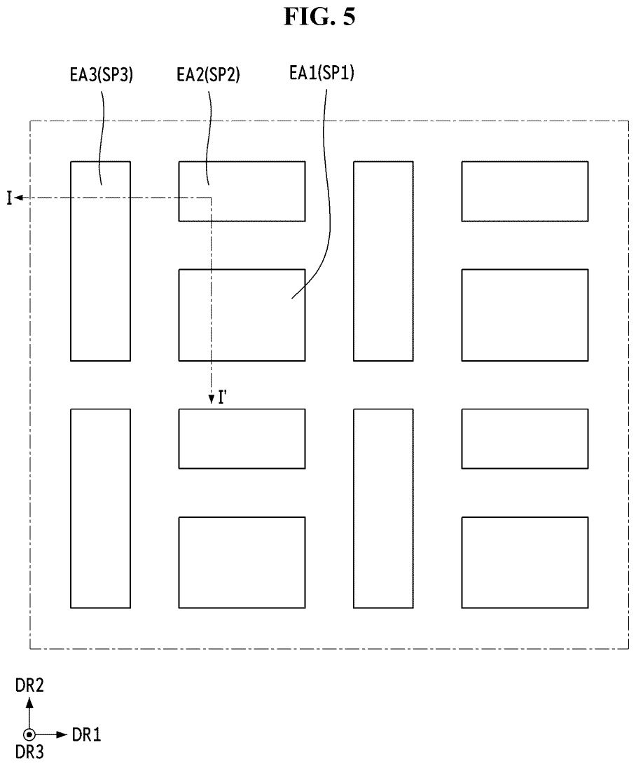

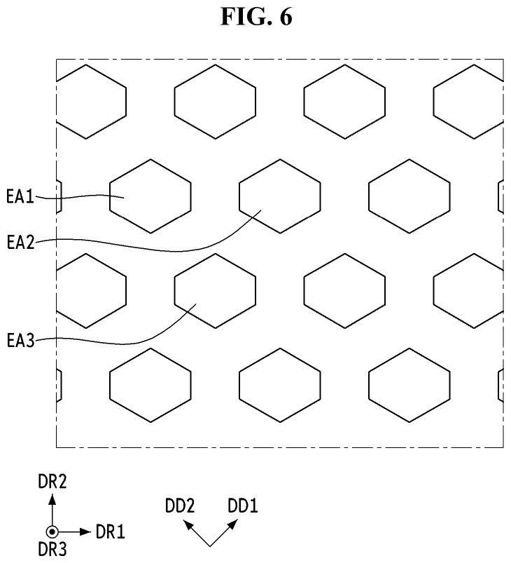

FIG. 5 is a schematic plan view illustrating an embodiment of the display area shown in FIG. 4. FIG. 6 is a schematic plan view illustrating another embodiment of the display area shown in FIG. 4.

Referring to FIG. 5, each of the pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 7). For example, each of the first emission area EA1, the second emission area EA2, and the third emission area EA3 may be an area defined by a first pixel defining film PDL1 (see FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other in a plan view.

The first emission area EA1 may emit light of a first color, the second emission area EA2 may emit light of a second color, and the third emission area EA3 may emit light of a third color. The light of the first color may be light of a red wavelength band, the light of the second color may be light of a green wavelength band, and the light of the third color may be light of a blue wavelength band. For example, the blue wavelength band may be a wavelength band of light having a main peak wavelength in a range of about 370 nm to about 460 nm, the green wavelength band may be a wavelength band of light having a main peak wavelength in a range of about 480 nm to about 560 nm, and the red wavelength band may be a wavelength band of light having a main peak wavelength in a range of about 600 nm to about 750 nm.

In another embodiment, as shown in FIG. 6, the first emission area EA1, the second emission area EA2, and the third emission area EA3 may be disposed in a hexagonal structure having a hexagonal shape in a plan view. The first emission area EA1 and the second emission area EA2 may be adjacent to each other in the first direction DR1, the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 5 and 6 that each of the pixels PX includes three emission areas EA1, EA2, and EA3, the disclosure is not limited thereto. For example, each of the pixels PX may include four emission areas. Further, each of the emission areas EA1, EA2, and EA3 may have a polygonal, circular, elliptical, or atypical shape in a plan view, unlike the embodiments shown in FIGS. 5 and 6.

The arrangement of the emission areas EA1, EA2, and EA3 of the pixels PX is not limited to the embodiments illustrated in FIGS. 5 and 6. For example, the emission areas of the pixels PX may be disposed in a stripe structure in which the emission areas are arranged in the first direction DR1, a PenTile® structure in which the emission areas are arranged in a diamond shape, or the like.

FIG. 7 is a schematic cross-sectional view illustrating an embodiment of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP may include the semiconductor substrate SSUB including multiple pixel transistors PTR, multiple semiconductor insulating films covering the pixel transistors PTR, and multiple contact terminals CTE electrically connected to the pixel transistors PTR, respectively. The pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. Multiple well regions WA may be disposed at top surface portions of the semiconductor substrate SSUB. The well regions WA may be regions doped with a second type impurity. The second type impurity may be different from the aforementioned first type impurity. For example, in case that the first type impurity is a p-type impurity, the second type impurity may be an n-type impurity. For example, in case that the first type impurity is an n-type impurity, the second type impurity may be a p-type impurity.

Each of the well regions WA may include a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than an impurity concentration of the source region SA. The second low-concentration impurity region LDD2 may be a region having an impurity concentration lower than an impurity concentration of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that may be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the disclosure is not limited thereto.

The contact terminals CTE may be disposed on the second semiconductor insulating film SINS2. Each of the contact terminals CTE may be connected to one of the gate electrode GE, the source region SA, and the drain region DA of each of the pixel transistors PTR through contact plugs penetrating the first semiconductor insulating film SINS1 and the second semiconductor insulating film INS2. The contact terminals CTE may be formed of at least one of copper (Cu), aluminum (Al), tungsten (W), molybdenum (Mo), chromium (Cr), gold (Au), titanium (Ti), nickel (Ni), neodymium (Nd), and an alloy thereof.

A third semiconductor insulating film SINS3 may be disposed on side surfaces of the contact terminals CTE. The top surface of each of the contact terminals CTE may be exposed without being covered by the third semiconductor insulating film SINS3. The third semiconductor insulating film SINS3 may be formed of a silicon oxide (SiOₓ)-based inorganic film, but the disclosure is not limited thereto.

The semiconductor substrate SSUB may be replaced with a glass substrate or a polymer resin substrate including polyimide, and thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include multiple conductive layers ML1 to ML8, multiple vias VA1 to VA9, and multiple insulating films INS1 to INS9. The insulating films INS1 to INS9 may be used for electrical insulation between the conductive layers ML1 to ML8.

The first to eighth conductive layers ML1 to ML8 may be connected to the contact terminals CTE exposed from the semiconductor backplane SBP, and serve to implement the circuit of the first sub-pixel SP1 shown in FIG. 3. For example, the first to sixth transistors T1 to T6 may be merely formed in the semiconductor backplane SBP, and the connection of the first to sixth transistors T1 to T6 and the first and second capacitors C1 and C2 may be implemented by the first to eighth conductive layers ML1 to ML8. The connection between the drain region corresponding to the drain electrode of the fourth transistor T4, the source region corresponding to the source electrode of the fifth transistor T5, and a first electrode AND of the light-emitting element LE (see FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may be made of substantially a same material. The first to eighth conductive layers ML1 to ML8 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. The first to eighth vias VA1 to VA8 may be made of substantially a same material. The first to eighth vias VA1 to VA8 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. First to eighth insulating films INS1 to INS8 may be formed of a silicon oxide (SiOₓ)-based inorganic film, but the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the disclosure is not limited thereto.

Each of the ninth vias VA9 may penetrate the ninth insulating film INS9 and be connected to the eighth conductive layer ML8. The ninth vias VA9 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first reflective electrodes RL1 may include titanium nitride (TiN).

Each of the second reflective electrodes RL2 may be disposed on the first reflective electrode RL1. The second reflective electrodes RL2 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. The second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RLA to advantageously reflect the light of the third color emitted from the light-emitting stack ES.

The first step layer STPL1 and the second step layer STPL2 may be formed of silicon carbonitride (SiCN) or a silicon oxide (SiOₓ)-based inorganic film, but the disclosure is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the third reflective electrodes RL3 may include titanium nitride (TiN).

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include a metal having high reflectivity to advantageously reflect the light. Since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOₓ)-based inorganic film, but the disclosure is not limited thereto.

Each of the tenth vias VA10 may penetrate the tenth insulating film VA10 and be connected to the reflective electrode layer RL. The tenth vias VA10 may be formed of at least one of copper (Cu), aluminum (Al), tungsten (W), molybdenum (Mo), chromium (Cr), gold (Au), titanium (Ti), nickel (Ni), neodymium (Nd), and an alloy thereof.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. For example, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover an edge of the first electrode AND of each of the light-emitting elements LE. The pixel defining film PDL may serve to partition the first emission areas EA1, the second emission areas EA2, and the third emission areas EA3. For example, the pixel defining film PDL may have openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the disclosure is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of the pixel defining film may increase, and a first encapsulation inorganic film TFE1 may be cut off due to step coverage. Step coverage may be a ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not shown in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

The first to third light-emitting layers EML1, EML2, and EML3 may be respectively disposed in the openings of the pixel defining film PDL on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

The electron transporting layer ETL may be disposed on the first to third light-emitting layers EML1, EML2, and EML3 and the hole transporting layer HTL, and the electron injecting layer EIL may be disposed on the electron transporting layer ETL.

In another embodiment, although not shown, multiple trenches (not shown) may be disposed between the first to third emission areas EA1, EA2, and EA3. The trenches may have a ring shape respectively surrounding the first to third emission areas EA1, EA2, and EA3, and may penetrate the pixel defining film PDL. The hole injecting layer HIL and the hole transporting layer HTL formed on the first electrodes AND of the first to third emission areas EA1, EA2, and EA3 may be disconnected from each other by the trenches.

In another embodiment, the first to third light-emitting stacks ES1, ES2, and ES3 may be respectively disposed in the openings of the pixel defining film PDL, and may not be disposed on the pixel defining film PDL. The first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 by forming a micro-cavity.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include a first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films including at least one of silicon nitride (SiNₓ), silicon oxy nitride (SiON), and silicon oxide (SiOₓ) are alternately stacked each other. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but the disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film including an acrylic resin, an epoxy resin, a phenolic resin, a polyamide resin, or a polyimide resin.

The cover layer CVL may be disposed on the adhesive layer APL. The cover layer CVL may be a glass substrate or a polymer resin. In case that the cover layer CVL is a glass substrate, the cover layer CVL may be attached onto the adhesive layer APL, and may serve as an encapsulation substrate. In case that the cover layer CVL is a polymer resin, the cover layer CVL may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the disclosure is not limited thereto.

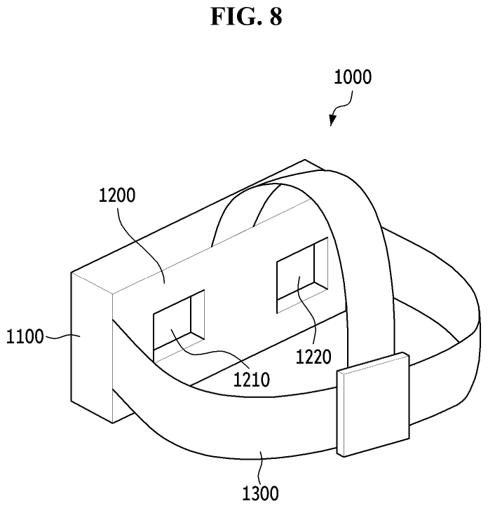

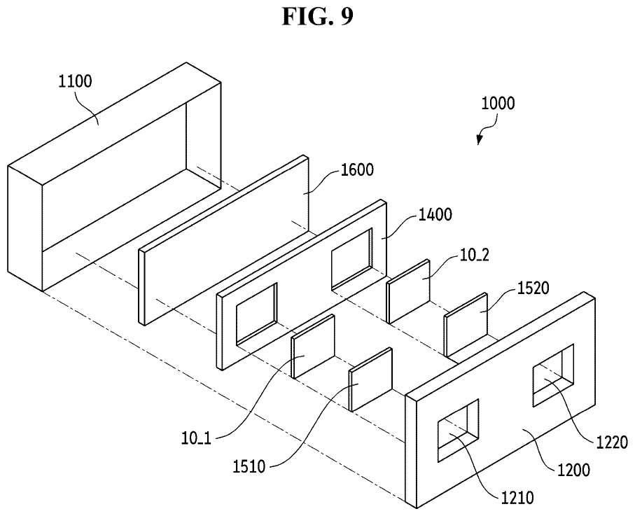

FIG. 8 is a schematic perspective view illustrating a head mounted display. FIG. 9 is a schematic exploded perspective view illustrating an embodiment of the head mounted display shown in FIG. 8.

Referring to FIGS. 8 and 9, a head mounted display 1000 according to one embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 may support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source input from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In another embodiment, the control circuit board 1600 may transmit a same digital video data DATA to the first display device 10_1 and the second display device 10_2.

The display device housing 1100 may accommodate the first display device 10_1, the second display device 10_2, the middle frame 1400, the first optical member 1510, the second optical member 1520, and the control circuit board 1600. The housing cover 1200 may cover an open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the disclosure is not limited thereto. In another embodiment, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

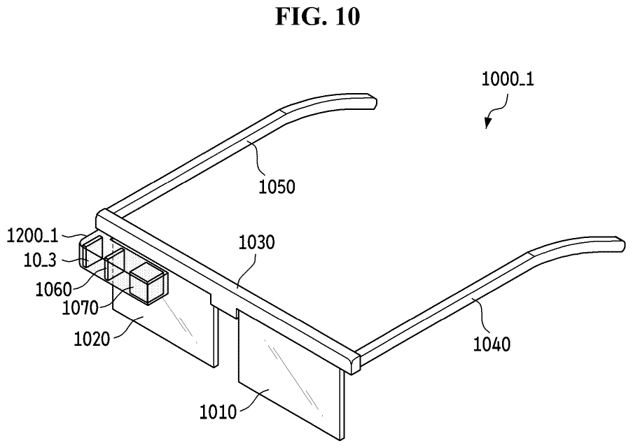

The head mounted band 1300 may secure the display device housing 1100 to the user's head such that the first eyepiece 1210 and the second eyepiece 1220 of the housing cover 1200 remain located on the user's left and right eyes, respectively. In case that the display device housing 1100 is implemented to be lightweight and compact, the head mounted display 1000 may be provided in the form of glasses as shown in FIG. 10.

The head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another embodiment of a head mounted display.

Referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the disclosure is not limited thereto. In another embodiment, the display device housing 1200_1 may be disposed at the left end of the support frame 1030, and the image of the display device 10_3 may be provided to the user's left eye. In another embodiment, the display device housing 1200_1 may be disposed at both the left and right ends of the support frame 1030, and the user may view the image displayed on the display device 10_3 through both the left and right eyes.

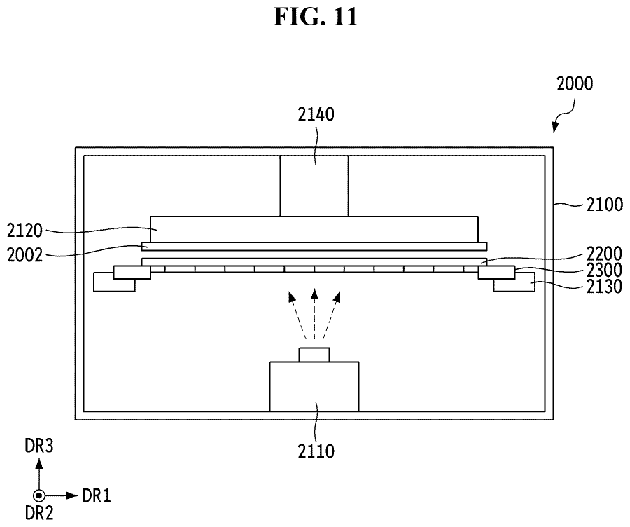

FIG. 11 is a schematic cross-sectional view illustrating a mask stage and a deposition apparatus including the mask stage according to one embodiment of the disclosure.

Referring to FIG. 11, a deposition apparatus 2000 according to one embodiment of the disclosure may be used to form an inorganic or organic material layer on a substrate 2002 (or a backplane substrate). According to one embodiment of the disclosure, a deposition apparatus 2000 may be used to form light-emitting layers of the light-emitting stack ES on the substrate 2002 in a manufacturing process of the display panel 100 (see FIG. 1). For example, as illustrated in FIG. 7, the semiconductor backplane SBP and the light emitting element backplane EBP may be disposed on the substrate 2002, and the reflective electrodes RL and the insulating film INS10 may be disposed on the light emitting element backplane EBP. Electrode patterns, for example, the first electrodes AND may be disposed on the insulating film INS10, and the first electrodes AND may be electrically connected to the reflective electrodes RL through the vias VA10. For example, the deposition apparatus 2000 may be used to form light-emitting layers on the electrode patterns. As an example, the deposition apparatus 2000 may be used to form first light-emitting layers for emitting first light having a red wavelength band on electrode patterns of the first emission areas EA1. As another example, the deposition apparatus 2000 may be used to form second light-emitting layers for emitting second light having a green wavelength band on electrode patterns of the second emission areas EA2. As still another example, the deposition apparatus 2000 may be used to form third light-emitting layers for emitting third light having a blue wavelength band on electrode patterns of the third emission areas EA3.

For example, the deposition apparatus 2000 according to one embodiment of the disclosure may include a process chamber 2100, a deposition source 2110 disposed in the process chamber 2100, a mask stage 2300 disposed above the deposition source 2110 and on which the deposition mask 2200 is placed, an upper chuck 2120 disposed above the mask stage 2300 to support the substrate 2002, and the like.

The process chamber 2100 may have an internal space, and a deposition process for forming a material layer on the substrate 2002 may be performed in the internal space of the process chamber 2100. The process chamber 2100 may be connected to a vacuum pump (not shown), and a vacuum atmosphere may be created in the internal space of the vacuum chamber 2100 by the vacuum pump.

The deposition source 2110 may be disposed in the process chamber 2100, and a deposition material may be stored in the deposition source 2110. The deposition source 2110 may evaporate the deposition material, such as an organic material, an inorganic material, or a conductive material, toward the substrate 2002, and the evaporated deposition material may be deposited on the substrate 2002 through the deposition mask 2200. For example, the deposition source 2110 may evaporate an organic material for forming light-emitting layers on the substrate 2002, and may have a heater (not shown) for evaporating the organic material. As shown in FIG. 11, the deposition source 2110 may be disposed on a lower central portion of the process chamber 2100. However, the disclosure is not limited to the embodiment shown in FIG. 11, and in another embodiment, the deposition source 2110 may be configured to be movable by a separate driver (not shown).

The mask stage 2300 on which the deposition mask 2200 is placed may be disposed above the deposition source 2110. The mask stage 2300 may be configured to be movable and rotatable by a lower driver 2130. For example, the lower driver 2130 may adjust the position of the mask stage 2300 to adjust the position of the deposition mask 2200 placed on the mask stage 2300, and may rotate the mask stage 2300 to adjust the angle of the deposition mask 2200.

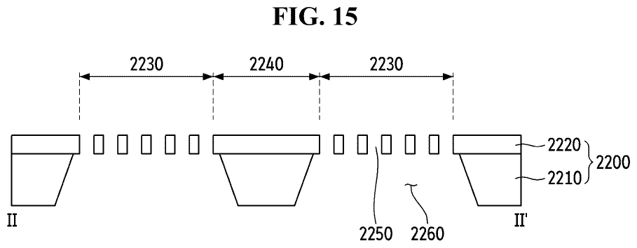

The deposition mask 2200 may include pixel openings 2250 (see FIG. 15) and cell openings 2260 (see FIG. 15) for providing the organic material evaporated from the deposition source 2110 onto the substrate 2002, and the mask stage 2300 may support the edge portion of the deposition mask 2200.

The upper chuck 2120 for supporting the substrate 2002 may be disposed above the mask stage 2300. An electrostatic chuck may be used as the upper chuck 2120, and the upper chuck 2120 may hold the substrate 2002 using an electrostatic force such that the substrate 2002 faces downward, for example, the substrate 2002 faces the deposition mask 2200. The substrate 2002 may be disposed with the front surface facing downward, and the upper chuck 2120 may hold the back surface of the substrate 2002 using an electrostatic force.

The upper chuck 2120 may be configured to be movable and rotatable by an upper driver 2140. For example, the upper driver 2140 may adjust the position of the upper chuck 2120 to adjust the position of the substrate 2002, and may rotate the upper chuck 2120 to adjust the angle of the substrate 2002.

After the deposition mask 2200 is placed on the mask stage 2300 and the substrate 2002 is held by the upper chuck 2120, positional alignment between the substrate 2002 and the deposition mask 2200 may be performed. After the positional alignment between the substrate 2002 and the deposition mask 2200 is performed, the upper chuck 2120 may move downward or the mask stage 2300 may move upward and, thus, the deposition mask 2200 may be brought into close contact with the front surface of the substrate 2002.

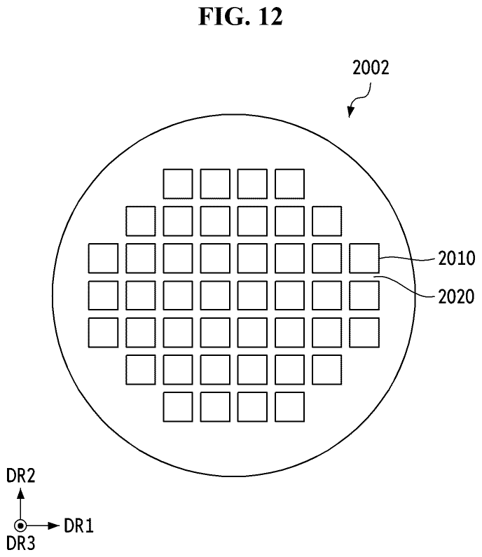

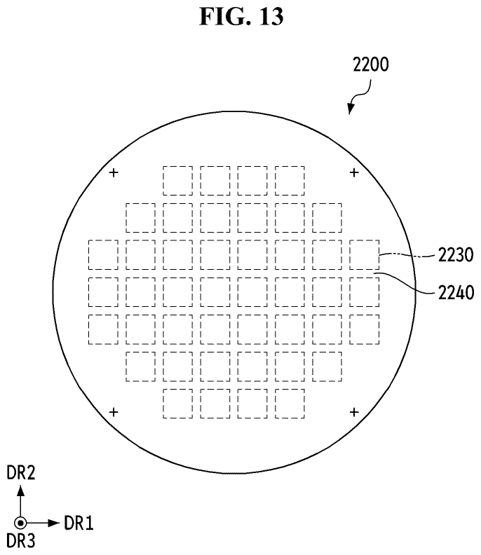

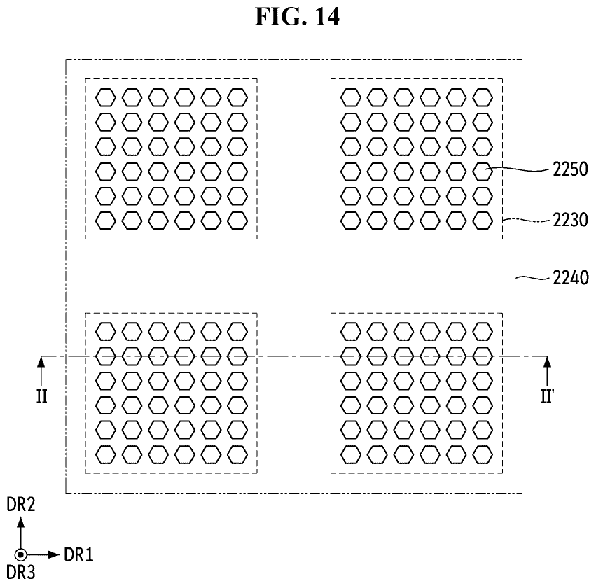

FIG. 12 is a schematic plan view illustrating the substrate shown in FIG. 11. FIG. 13 is a schematic plan view illustrating the deposition mask shown in FIG. 11. FIG. 14 is a schematic enlarged plan view illustrating the mask cell region shown in FIG. 13. FIG. 15 is a schematic cross-sectional view taken along line II-II′ shown in FIG. 14.

Referring to FIGS. 12 to 15, the deposition mask 2200 according to one embodiment of the disclosure may be used as a shadow mask in a deposition process for forming organic light-emitting layers on the substrate 2002.

The substrate 2002 may include multiple display cell regions 2010 and a scribe lane region 2020 disposed between the display cell regions 2010. As shown in FIG. 12, the display cell regions 2010 may be arranged in a matrix form along the first direction DR1 and the second direction DR2 intersecting the first direction DR1. For example, the first direction DR1 may be a first horizontal direction, and the second direction DR2 may be a second horizontal direction perpendicular to the first direction DR1. However, the number and arrangement directions of the display cell regions 2010 may be variously changed, and the scope of the disclosure is not limited by this.

Each of the display cell regions 2010 may include the semiconductor backplane SBP (see FIG. 7), the light-emitting element backplane EBP (see FIG. 7) disposed on the semiconductor backplane SBP, the reflective electrode layer RL (see FIG. 7) disposed on the light-emitting element backplane EBP, and the insulating film INS10 (see FIG. 7) disposed on the reflective electrode layer RL. For example, each of the display cell regions 2010 may include the anode electrodes AND (see FIG. 7) disposed on the insulating film INS10. For example, the anode electrodes AND may be disposed on the front surface of the substrate 2002.

The deposition mask 2200 may include a mask frame 2210 and a membrane 2220 disposed on the mask frame 2210. Further, the deposition mask 2200 may include multiple mask cell regions 2230 respectively corresponding to the display cell regions 2010 and a grid region 2240 disposed between the mask cell regions 2230. Each of the mask cell regions 2230 may have multiple pixel openings 2250 for exposing the anode electrodes AND in the deposition process. The pixel openings 2250 may be formed to penetrate the membrane 2220, and the mask frame 2210 may have multiple cell openings 2260 for respectively exposing the mask cell regions 2230. For example, the mask cell regions 2230 may be respectively disposed on the cell openings 2260, and the pixel openings 2250 may communicate with the cell openings 2260.

As shown in FIG. 13, the mask cell regions 2230 may be arranged in a matrix form along the first direction DR1 and the second direction DR2 intersecting the first direction DR1. For example, the first direction DR1 may be a first horizontal direction, and the second direction DR2 may be a second horizontal direction perpendicular to the first direction DR1. For example, the mask cell regions 2230 may be arranged to respectively correspond to the display cell regions 2010 of the substrate 2002. However, the number and arrangement directions of the mask cell regions 2230 may be variously changed, and the disclosure is not limited thereto.

The cell openings 2260 of the mask frame 2210 may be formed to expose the mask cell regions 2230 by a dry or wet etching process after the pixel openings 2250 of the membrane 2220 are formed. For example, a semiconductor substrate such as a silicon wafer may be used as the mask frame 2210. Although not shown, the mask frame 2210 may include an inorganic film (not shown) formed on the silicon wafer. The cell openings 2260 may be formed to penetrate the silicon wafer and the inorganic film. For example, a silicon oxide film formed by a thermal oxidation process or a chemical vapor deposition process may be used as the inorganic film.

The membrane 2220 and the inorganic film may be made of different materials. For example, the membrane 2220 may be formed of a silicon nitride film formed by a chemical vapor deposition process. The inorganic film may function as an adhesive film between the silicon wafer and the membrane 2220. However, the disclosure is not limited thereto, and the membrane 2220 may be made of a material other than silicon nitride film.

The pixel openings 2250 of the membrane 2220 may function as paths for providing an organic material in the deposition process for forming organic light-emitting layers on the substrate 2002. For example, the pixel openings 2250 may be arranged to correspond to the anode electrodes AND of each of the display cell regions 2010. For example, as shown in FIG. 14, the pixel openings 2250 may be arranged in a matrix form along the first direction DR1 and the second direction DR2, and may be formed to penetrate the membrane 2220 by an anisotropic etching process after the membrane 2220 is formed on the inorganic film. The inorganic film may function as an etching stop film during the anisotropic etching process.

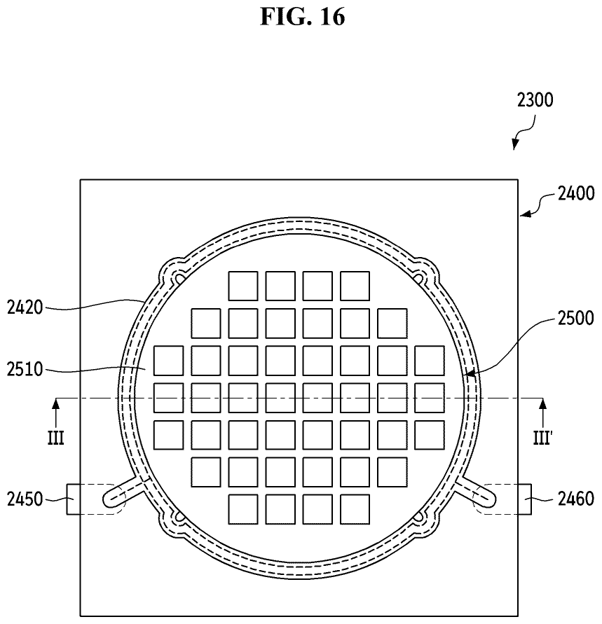

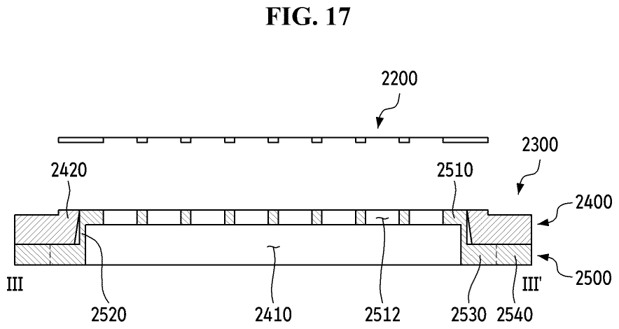

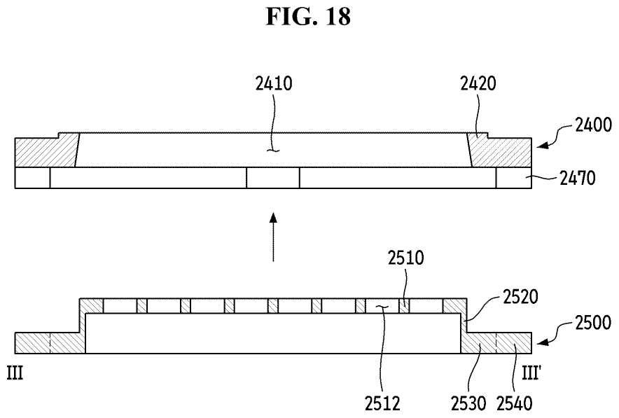

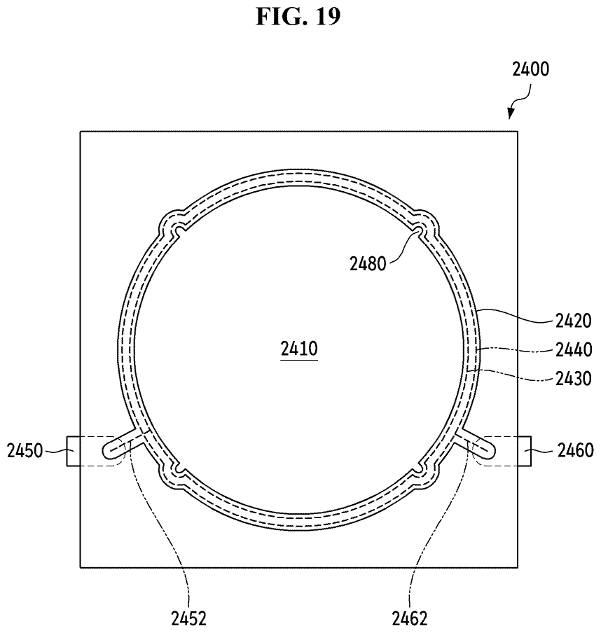

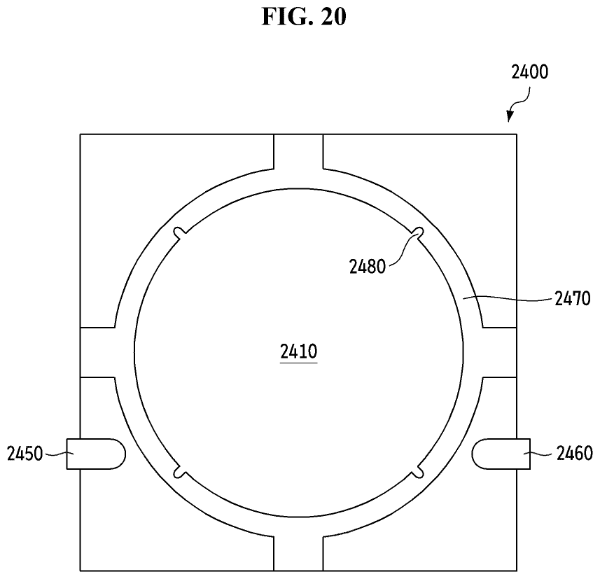

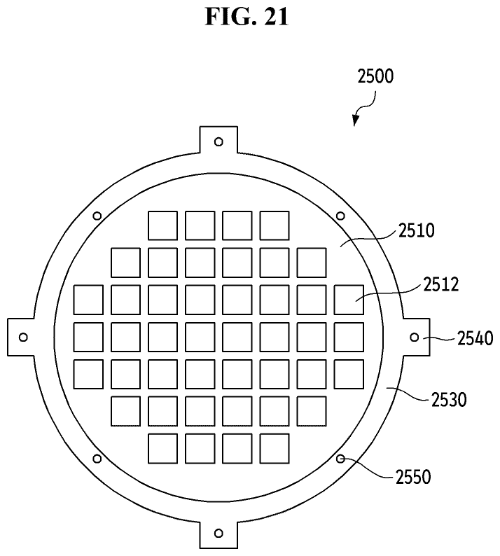

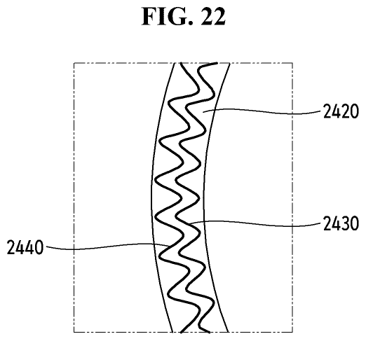

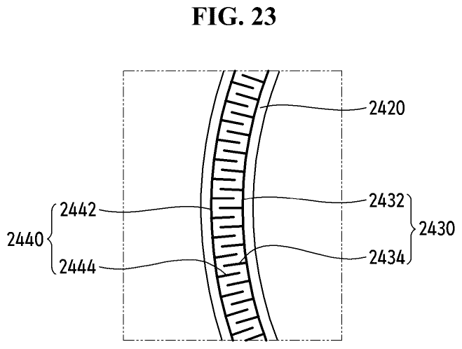

FIG. 16 is a schematic plan view illustrating the mask stage shown in FIG. 11. FIG. 17 is a schematic cross-sectional view taken along line III-III′ shown in FIG. 16. FIG. 18 is a schematic cross-sectional view illustrating the electrostatic chuck and the lattice support shown in FIG. 17. FIG. 19 is a schematic plan view illustrating the electrostatic chuck shown in FIG. 16. FIG. 20 is a schematic bottom view illustrating the electrostatic chuck shown in FIG. 16. FIG. 21 is a schematic plan view illustrating the lattice support shown in FIG. 16. FIG. 22 is a schematic enlarged plan view illustrating first and second electrostatic electrodes shown in FIG. 16. FIG. 23 is a schematic enlarged plan view illustrating another embodiment of the first and second electrostatic electrodes shown in FIG. 22.

Referring to FIGS. 16 to 23, the mask stage 2300 may be used to fix the position of the deposition mask 2200 and support the deposition mask 2200 in the process chamber 2100. In accordance with one embodiment of the disclosure, the mask stage 2300 may include an electrostatic chuck 2400 for holding the deposition mask 2200 using an electrostatic force.

As shown in FIGS. 19 and 20, the electrostatic chuck 2400 may have a plate shape in a plan view through which a through hole 2410 is formed. For example, the electrostatic chuck 2400 may have a quadrilateral plate shape having the circular through hole 2410. For example, the electrostatic chuck 2400 may include a circular ring-shaped chucking region 2420 that is disposed around the through hole 2410 to hold the edge portion of the deposition mask 2200 using an electrostatic force. For example, the edge portion of the deposition mask 2200 may be placed on the chucking region 2420, and the chucking region 2420 may hold the edge portion of the deposition mask 2200 using an electrostatic force.

The mask stage 2300 may include a lattice support 2500 for supporting the remaining portion of the deposition mask 2200 except the edge portion. The lattice support 2500 may be disposed in the through hole 2410 of the electrostatic chuck 2400 as shown in FIG. 16, and may include a lattice plate 2510 for supporting the grid region 2240 of the deposition mask 2200 and a support ring 2520 extending downward from the edge portion of the lattice plate 2510 as shown in FIGS. 17 and 18.

For example, the lattice plate 2510 may have a disc shape, and the support ring 2520 may have a circular ring shape in a plan view. The lattice plate 2510 and the support ring 2520 may be inserted into the through hole 2410 of the electrostatic chuck 2400 as shown in FIG. 18. As shown in FIG. 17, the top surface of the chucking region 2420 of the electrostatic chuck 2400 and the top surface of the lattice plate 2510 may be disposed at a same height so that the deposition mask 2200 may be supported evenly.

The chucking region 2420 of the electrostatic chuck 2400 may have a circular ring shape corresponding to the edge portion of the deposition mask 2200. In accordance with one embodiment of the disclosure, a first electrostatic electrode 2430 and a second electrostatic electrode 2440 may be disposed in the chucking region 2420 of the electrostatic chuck 2400. A first electrostatic voltage may be applied to the first electrostatic electrode 2430, and a second electrostatic voltage having a polarity different from the first electrostatic voltage may be applied to the second electrostatic electrode 2440. For example, a positive voltage may be applied to the first electrostatic electrode 2430, and a negative voltage may be applied to the second electrostatic electrode 2440.

The electrostatic chuck 2400 may be made of a ceramic material such as aluminum oxide (Al₂O₃), aluminum nitride (AlN), or yttrium oxide (Y₂O₃), and may be manufactured by a pressure sintering and/or thermal spray coating process. The first electrostatic electrode 2430 and the second electrostatic electrode 2440 may include a metal material such as tungsten (W), molybdenum (Mo), or titanium (Ti), and may be formed by a pressure sintering or brazing process.

For example, the first electrostatic electrode 2430 may have a circular ring shape extending along the chucking region, and the second electrostatic electrode 2440 may have a circular ring shape surrounding the first electrostatic electrode 2430. For example, the first electrostatic electrode 2430 and the second electrostatic electrode 2440 may be disposed at a same height, and may be spaced apart from each other by a gap. For example, the first electrostatic electrode 2430 and the second electrostatic electrode 2440 may have a width in a range of about 0.3 mm to about 0.7 mm and a thickness of several tens to hundreds of μm, and the gap between the first electrostatic electrode 2430 and the second electrostatic electrode 2440 may be in a range of about 0.8 mm to about 1 mm.

The electrostatic chuck 2400 may include a first connector 2450 and a second connector 2460 for connecting the first electrostatic electrode 2430 and the second electrostatic electrode 2440 to an external power source (not shown). Although not shown in detail, the first connector 2450 may be connected to the first electrostatic electrode 2430 through a first connection wire 2452 and a first via contact (not shown), and the second connector 2460 may be connected to the second electrostatic electrode 2440 through a second connection wire 2462 and a second via contact (not shown). The first connection wire 2452 may be disposed under the first electrostatic electrode 2430, the second connection wire 2462 may be disposed under the second electrostatic electrode 2440, the first via contact may electrically connect the first connection wire 2452 to the first electrostatic electrode 2430, and the second via contact may electrically connect the second connection wire 2462 to the second electrostatic electrode 2440. However, the disclosure is not limited thereto, and the method of connecting the first and second electrostatic electrodes 2430 and 2440 to the external power source may be variously changed.

The electrostatic force applied to the deposition mask 2200 by the first and second electrostatic electrodes 2430 and 2440 may be proportional to the areas of the first and second electrostatic electrodes 2430 and 2440. In accordance with one embodiment of the disclosure, in order to increase the areas of the first and second electrostatic electrodes 2430 and 2440, the first and second electrostatic electrodes 2430 and 2440 may have a meandering structure. For example, as shown in FIG. 22, the first electrostatic electrode 2430 may have a meandering structure extending along the chucking region 2420, and the second electrostatic electrode 2440 may extend side by side with the first electrostatic electrode 2430.

In another embodiment, as shown in FIG. 23, the first electrostatic electrode 2430 may include a first ring electrode 2432 formed in a circular ring shape extending along the chucking region and multiple first branch electrodes 2434 extending radially outward from the first ring electrode 2432, and the second electrostatic electrode 2440 may include a second ring electrode 2442 formed in a circular ring shape surrounding the first electrostatic electrode 2430, and multiple second branch electrodes 2444 extending radially inward from the second ring electrode 2442. The first branch electrodes 2434 and the second branch electrodes 2444 may be alternately arranged in a circumferential direction.

The lattice support 2500 may be inserted into the through hole 2410 of the electrostatic chuck 2400 as shown in FIG. 18, and may be coupled to the bottom surface portion of the electrostatic chuck 2400. In accordance with one embodiment of the disclosure, the lattice support 2500 may include a flange 2530 surrounding the lower portion of the support ring 2520, and a mount bracket 2540 protruding radially outward from the flange 2530. A stepped portion 2470 into which the flange 2530 and the mount bracket 2540 of the lattice support 2500 are inserted may be provided at the bottom surface portion of the electrostatic chuck 2400. For example, as shown in FIG. 21, the flange 2530 may have a circular ring shape in a plan view, four mount brackets 2540 may protrude outward in the radial direction of the lattice support 2500 from the flange 2530, and the lattice support 2500 may be coupled into the stepped portion 2470 and the through hole 2410 of the electrostatic chuck 2400 by fastening members (not shown) coupled to the electrostatic chuck 2400 through the mount brackets 2540.

In accordance with one embodiment of the disclosure, the lattice plate 2510 of the lattice support 2500 may support the cell regions 2230 of the deposition mask 2200. For example, as shown in FIGS. 16 and 21, the lattice plate 2510 may have lattice holes 2512 respectively corresponding to the cell openings 2260 of the deposition mask 2200, and may support the grid region 2240 of the deposition mask 2200. For example, the flatness of the top surface of the lattice plate 2510 may be several μm or less so that the deposition mask 2200 may be sufficiently brought into close contact with the substrate 2002. For example, the top surface of the lattice plate 2510 may have a flatness of less than or equal to about 3 μm.

The top surface of the lattice plate 2510 may be processed to have a flatness of less than or equal to about 3 μm by a polishing process. However, if the thickness of the lattice plate 2510 is excessively thin, for example, if the thickness thereof is about 4 mm or less, deformation of the lattice plate 2510 may occur during the polishing process, and if the thickness of the lattice plate 2510 is excessively thick, for example, if the thickness thereof exceeds about 6 mm, a shadow area may be generated on the substrate 2002 by the lattice plate 2510 during the deposition process. Accordingly, the lattice plate 2510 may have a thickness in a range of about 5 mm to about 6 mm.

In accordance with one embodiment of the disclosure, the lattice support 2500 may be made of stainless steel. For example, in order to prevent deformation of the lattice plate 2510 during the polishing process for the top surface of the lattice plate 2510, the lattice support 2500 may be made of precipitation hardening stainless steel having an improved yield strength. For example, the lattice support 2500 may be made of precipitation hardening stainless steel such as STS630 and STS631.

Although not shown, an alignment camera (not shown) for aligning the position of the deposition mask 2200 may be disposed in the process chamber 2100, and the deposition mask 2200 may have an alignment key for position alignment. For example, the alignment key may be disposed on the bottom surface of the edge portion of the deposition mask 2200, and the mask stage 2300 may have an alignment hole for detecting the alignment key of the deposition mask 2200. For example, the lattice support 2500 may have multiple alignment holes 2550 penetrating the flange 2530 as shown in FIG. 21, and the electrostatic chuck 2400 may have alignment slots 2480 respectively corresponding to the alignment holes 2550 of the lattice support 2500 as shown in FIGS. 19 and 20. The alignment key of the deposition mask 2200 may be detected by the alignment camera through the alignment holes 2550 of the lattice support 2500 and the alignment slots 2480 of the electrostatic chuck 2400. The alignment slots 2480 may be formed at the inner surface portions of the through hole 2410 of the electrostatic chuck 2400, and may be covered by the outer surface of the lattice support 2500, for example, the outer surface of the support ring 2520. For example, the alignment slots 2480 may penetrate the chucking region 2420 of the electrostatic chuck 2400 in a vertical direction. As shown in FIGS. 16 and 19, the first electrostatic electrode 2430 and the second electrostatic electrode 2440 may be formed to bypass the alignment slots 2480. As shown in the drawings, four alignment holes 2550 and four alignment slots 2480 may be used, but the disclosure is not limited thereto, and the number of alignment holes 2550 and alignment slots 2480 may be variously changed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask stage comprising:
an electrostatic chuck having a plate shape in a plan view through which a through hole is formed and supporting an edge portion of a deposition mask; and
a lattice support disposed in the through hole and supporting a remaining portion of the deposition mask other than the edge portion,
wherein the electrostatic chuck comprises a chucking region having a ring shape in a plan view disposed around the through hole to hold the edge portion of the deposition mask using an electrostatic force.

2. The mask stage of claim 1, wherein
the deposition mask comprises a plurality of cell regions and a grid region disposed between the plurality of cell regions, and
the lattice support comprises a lattice plate supporting the grid region of the deposition mask, and a support ring extending downward from an edge portion of the lattice plate.

3. The mask stage of claim 2, wherein the lattice plate has a thickness in a range of about 5 mm to about 6 mm.

4. The mask stage of claim 2, wherein
the lattice support further comprises a flange surrounding a lower portion of the support ring and a mount bracket protruding radially outward from the flange, and
a stepped portion into which the flange and the mount bracket are inserted is provided at a bottom surface portion of the electrostatic chuck.

5. The mask stage of claim 1, wherein the lattice support is made of precipitation hardening stainless steel.

6. The mask stage of claim 1, wherein
the electrostatic chuck further comprises:
a first electrostatic electrode disposed in the chucking region; and
a second electrostatic electrode disposed in the chucking region,
a first electrostatic voltage is applied to the first electrostatic electrode, and
a second electrostatic voltage having a polarity different from the first electrostatic voltage is applied to the second electrostatic electrode.

7. The mask stage of claim 6, wherein
the chucking region has a circular ring shape in a plan view,
the first electrostatic electrode has a circular ring shape in a plan view extending along the chucking region,
the second electrostatic electrode has a circular ring shape in a plan view surrounding the first electrostatic electrode, and is spaced apart from the first electrostatic electrode by a gap, and
the first electrostatic electrode and the second electrostatic electrode are disposed at a same height.

8. The mask stage of claim 7, wherein
the first electrostatic electrode has a meandering structure extending along the chucking region, and
the second electrostatic electrode extends along the first electrostatic electrode.

9. The mask stage of claim 6, wherein
the chucking region has a circular ring shape in a plan view,
the first electrostatic electrode comprises a first ring electrode formed in a circular ring shape in a plan view extending along the chucking region, and a plurality of first branch electrodes extending radially outward from the first ring electrode,
the second electrostatic electrode comprises a second ring electrode formed in a circular ring shape in a plan view surrounding the first electrostatic electrode, and a plurality of second branch electrodes extending radially inward from the second ring electrode, and
the plurality of first branch electrodes and the plurality of second branch electrodes are alternately arranged in a circumferential direction.

10. A deposition apparatus comprising:
a deposition source;
a mask stage disposed above the deposition source and on which a deposition mask is placed; and
an upper chuck disposed above the mask stage to hold a back surface of a substrate such that a front surface of the substrate faces the deposition mask, wherein
the mask stage comprises:
an electrostatic chuck having a plate shape through which a through hole is formed and supporting an edge portion of the deposition mask; and
a lattice support disposed in the through hole and supporting a remaining portion of the deposition mask other than the edge portion, and
the electrostatic chuck comprises a chucking region having a ring shape in a plan view disposed around the through hole to hold the edge portion of the deposition mask using an electrostatic force.

11. The deposition apparatus of claim 10, wherein
the deposition mask comprises a plurality of cell regions and a grid region disposed between the plurality of cell regions, and
the lattice support comprises a lattice plate supporting the grid region of the deposition mask, and a support ring extending downward from an edge portion of the lattice plate.

12. The deposition apparatus of claim 11, wherein the lattice plate has a thickness in a range of about 5 mm to about 6 mm.

13. The deposition apparatus of claim 11, wherein
the lattice support further comprises a flange surrounding a lower portion of the support ring and a mount bracket protruding radially outward from the flange, and
a stepped portion into which the flange and the mount bracket are inserted is provided at a bottom surface portion of the electrostatic chuck.

14. The deposition apparatus of claim 13, wherein
the lattice support has an alignment hole penetrating the flange,
the electrostatic chuck has an alignment slot corresponding to the alignment hole and formed at an inner surface portion of the through hole, and
an alignment key of the deposition mask is aligned with the alignment hole and the alignment slot.

15. The deposition apparatus of claim 10, wherein the mask stage has an alignment hole aligned with an alignment key of the deposition mask.

16. The deposition apparatus of claim 10, wherein the lattice support is made of precipitation hardening stainless steel.

17. The deposition apparatus of claim 10, wherein
the electrostatic chuck further comprises:
a first electrostatic electrode disposed in the chucking region; and
a second electrostatic electrode disposed in the chucking region,
a first electrostatic voltage is applied to the first electrostatic electrode, and
a second electrostatic voltage having a polarity different from the first electrostatic voltage is applied to the second electrostatic electrode.

18. The deposition apparatus of claim 17, wherein
the chucking region has a circular ring shape in a plan view,
the first electrostatic electrode has a circular ring shape in a plan view extending along the chucking region,
the second electrostatic electrode has a circular ring shape in a plan view surrounding the first electrostatic electrode, and is spaced apart from the first electrostatic electrode by a predetermined gap, and
the first electrostatic electrode and the second electrostatic electrode are disposed at a same height.

19. The deposition apparatus of claim 18, wherein
the first electrostatic electrode has a meandering structure extending along the chucking region, and
the second electrostatic electrode extends along the first electrostatic electrode.

20. The deposition apparatus of claim 17, wherein
the chucking region has a circular ring shape in a plan view,
the first electrostatic electrode comprises a first ring electrode formed in a circular ring shape in a plan view extending along the chucking region, and a plurality of first branch electrodes extending radially outward from the first ring electrode,
the second electrostatic electrode comprises a second ring electrode formed in a circular ring shape in a plan view surrounding the first electrostatic electrode, and a plurality of second branch electrodes extending radially inward from the second ring electrode, and
the plurality of first branch electrodes and the plurality of second branch electrodes are alternately arranged in a circumferential direction.

21. An electronic device comprising:
a display panel comprising a substrate and light-emitting layers formed on the substrate by using a deposition apparatus comprising:
a deposition source;
a mask stage disposed above the deposition source and on which a deposition mask is placed; and
an upper chuck disposed above the mask stage to hold a back surface of the substrate such that a front surface of the substrate faces the deposition mask, wherein
the mask stage comprises:
an electrostatic chuck having a plate shape through which a through hole is formed and supporting an edge portion of the deposition mask; and
a lattice support disposed in the through hole and supporting a remaining portion of the deposition mask other than the edge portion, and
the electrostatic chuck comprises a chucking region having a ring shape in a plan view disposed around the through hole to hold the edge portion of the deposition mask using an electrostatic force.
